(19) United States
(12) Patent Application Publication
(10) Pub. No.: US 2010/0041241 A1
(43) Pub. Date: Feb. 18, 2010

(54) HIGH DENSITY PLASMA DIELECTRIC DESPOSITION FOR VOID FREE GAP FILL

(75) Inventors: Joseph A. GALLEGOS, Dallas, TX (US); Bill Alan WOFFORD, Dallas, TX (US); Edward L. MICKLER, Dallas, TX (US); Duofeng YUE, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/540,130

(22) Filed: Aug. 12, 2009

Related U.S. Application Data
(60) Provisional application No. 61/088,082, filed on Aug. 12, 2008.

(51) Int. Cl. H01L 21/31

(52) U.S. Cl. 438/761; 257/E21.24

(57) ABSTRACT

A process for void free deposition of dielectric films over high aspect ratio structures using HDP CVD. In a dielectric liner deposition step and the etch to deposition ratio is increased and the deposition pressure is reduced to reduce the aspect ratio of the gap and to deposit a dielectric sidewall on the gap with a significant slope.

### FIELD OF THE INVENTION

This invention relates to the field of integrated circuits. More particularly, this invention relates to high density plasma dielectric deposition.

### BACKGROUND OF THE INVENTION

High density plasma (HDP) chemical vapor deposition (CVD) of dielectric films is used in semiconductor processing to deposit dielectric films over severe topography without forming voids. HDP CVD deposition combines an etching component as well as a deposition component. The etching component is more effective on upper surfaces and open areas than on the lower surfaces within a gap so the dielectric thickness increases at a faster rate on the lower surfaces within the gap aiding the gap to fill without a void. A conventional gap filling process using HDP oxide typically consists of a first deposition step that deposits a liner oxide to reduce the aspect ratio and a second deposition step to fill the gap and deposit the bulk of the dielectric film.

Semiconductor geometries have scaled to smaller dimensions faster in the horizontal dimensions than in the vertical dimension. This has been done is to slow the rate that lead resistance increases as the lead dimensions scale. The result of scaling dimensions faster horizontally than vertically is an increase in aspect ratio making gap fill increasingly more challenging.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

The deposition conditions of liner oxide in a two step HDP oxide gap fill process have been carefully optimized to reduce the aspect ratio of the gap and also to provide the gap with sloped sidewalls. This new liner process enables gaps with higher aspect ratios to be filled void free.

### DESCRIPTION OF THE VIEWS OF THE DRAWING

FIG. 1 (Prior art) Crossection of a conventional HDP gap fill liner process.

FIG. 2. Crossection of a HDP gap fill liner process according to an embodiment.

FIG. 3A (Prior Art) Crossection through a void formed during a conventional HDP gapfill process.

FIG. 3B (Prior Art) Crossection through metal containing filaments formed with a conventional HDP gapfill process.

FIGS. 4A and 4B. Crossections of a HDP gap fill process according to an embodiment.

FIG. 5. Cumulative voltage breakdown distributions of dielectric films deposited with a conventional HDP process and deposited with a process according to an embodiment HDP process.

### DETAILED DESCRIPTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

High density plasma deposition of dielectric films is used to deposit dielectrics over severe topography without forming voids. During the deposition, there is an etching component as well as a deposition component to the process. The etching component is more effective on upper surfaces than it is on lower surfaces so the dielectric thickness increases at a faster rate on the lower surfaces thus reducing the aspect ratio in narrow gaps. The etching to deposition ratio, E/D ratio, and the deposition pressure are key factors in controlling the gap filling capability of an HDP process. During HDP deposition the etching rate is primarily controlled by the partial pressure of Ar in the plasma and also by the high frequency power (HFRF). The deposition rate is primarily controlled by the SiH4 and O2 gas flow rates, temperature, pressure, and the low frequency power (LFRF).

Semiconductor geometries have scaled to smaller dimensions faster in the horizontal dimensions than in the vertical dimension. This is to slow the rate of resistance increase as the leads scale. The result of scaling dimensions faster horizontally than vertically is an increase in aspect ratio making void free gap fill increasingly more challenging.

The term “E/D ratio” refers to the ratio of the rate of etching of the dielectric film to the rate of the deposition of the dielectric film during a high density plasma (HDP) deposition.

The term “gap” refers to the trench that forms between two closely spaced structures. The aspect ratio of the gap is the ratio of the depth of the trench divided by the width of the trench.

The HDP gapfill process is typically done in two separate deposition steps with two different E/D ratios. The purpose of the first liner deposition step is to reduce the aspect ratio (depth/width) of the gap. The reduction in aspect ratio may enable the dielectric deposited during the second step to fill the reduced aspect ratio gap without forming a void. The purpose of the second deposition step is to fill the gap and to deposit the bulk of the dielectric film. In conventional HDP gapfill processes the first step liner process is done with a E/D ratio that is significantly lower than the E/D ratio of the second step liner process.

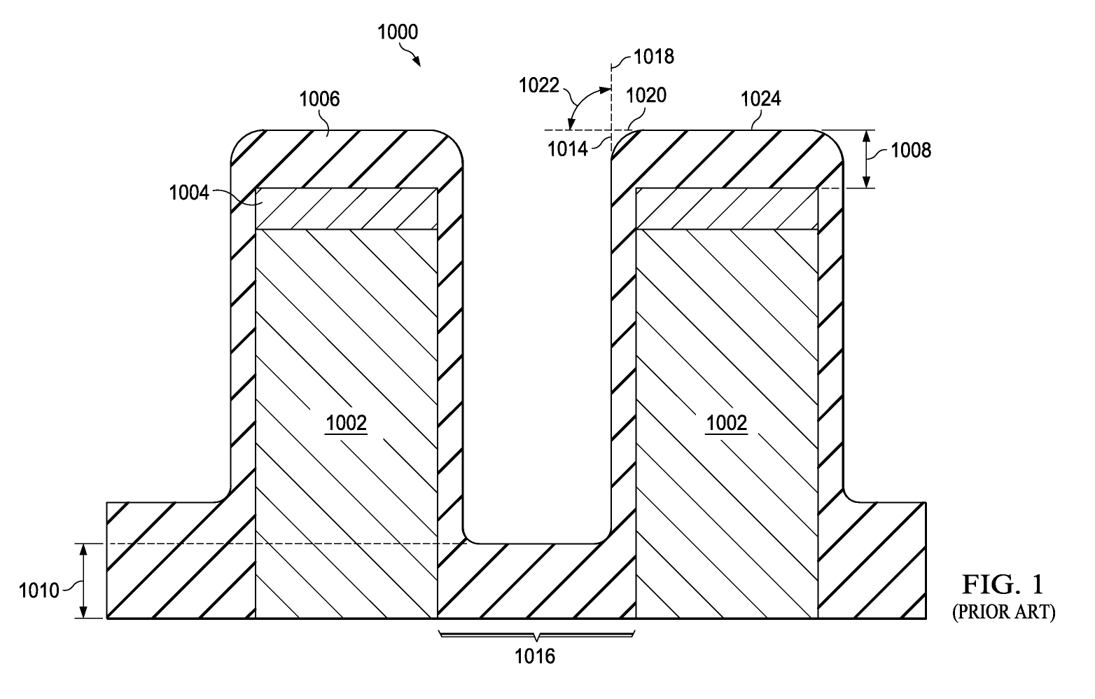

FIG. 1 shows a cross section through a gap formed between metal leads (1002) after step 1 liner deposition in a conventional HDP gap fill process. For purposes of illustration, aluminum metal leads (1002) with a TiN capping layer (1004) are shown. The minimum width leads (1002) are approximately 300 nm wide, 660 nm tall, and are separated from each other by approximately 200 nm. The aspect ratio of the gap (1016) is approximately 3.3. A dielectric liner (1006) in the conventional process is deposited at a low pressure of typically less than 2 milliTorr and with an E/D ratio of approximately 0.14. As shown in FIG. 1, deposition of the dielectric liner on top (1008) of the metal lead (1002) is thinner than it is at the bottom (1010) of the gap (1016). This reduces the aspect ratio of the gap. The dielectric liner in conventional gap fill is nearly conformal. The slope of the dielectric liner on sidewalls of the gap (1014) is substantially vertical (1018) and the slope (1020) of the surface of the dielectric liner on top of the lead (1008) is substantially horizontal (1020) after gap fill liner (1006) deposition. The angle (1022) between the slope of a line (1020) that is tangent to the surface of the dielectric at the center point (1024) of the dielectric on top of a minimum width lead (1002) and a vertical line (1018) is nearly a right angle. This results in a significant challenge to fill the gap (1016) without forming voids using a conventional HDP gapfill process, especially as dimensions continue to scale.

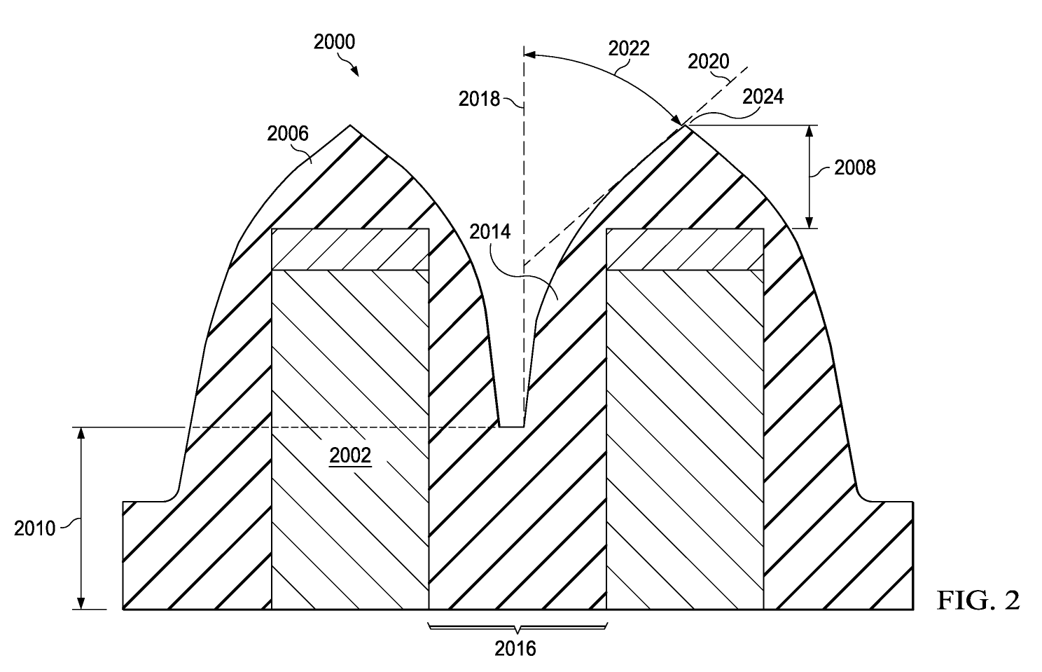

FIG. 2 shows a cross section through a gap (2016) formed between two minimum width metal leads (2002) after the first step liner deposition using an HDP process according to an embodiment of the instant invention. This gap (2016) also has a 3.3 aspect ratio. In this embodiment the gap fill liner (2006) is deposited at a low pressure in the range of 2 to 3 milliTorr and with an E/D ratio of approximately 0.22. As shown in FIG. 2, the aspect ratio is reduced since the thickness (2008) of the liner (2006) is less on top of the lead (2002) than the thickness (2010) at the bottom of the gap (2016). In addition to reduction in the aspect ratio, the sidewalls (2014) of the liner in the gap (2016) have a continuous slope from the peak that is formed in the middle on top of a minimum width lead (2002) downward to the sides of the gap (2016). This slope (2016) significantly facilitates the filling of gaps without forming voids. The angle (2022) between a line (2020) that is tangent to the surface of the dielectric at the dielectric peak (2024) that forms in the center on top of a minimum width lead (2002) as shown in FIG. 2 may range from 30 to 60 degrees but usually may be approximately 45 degrees.

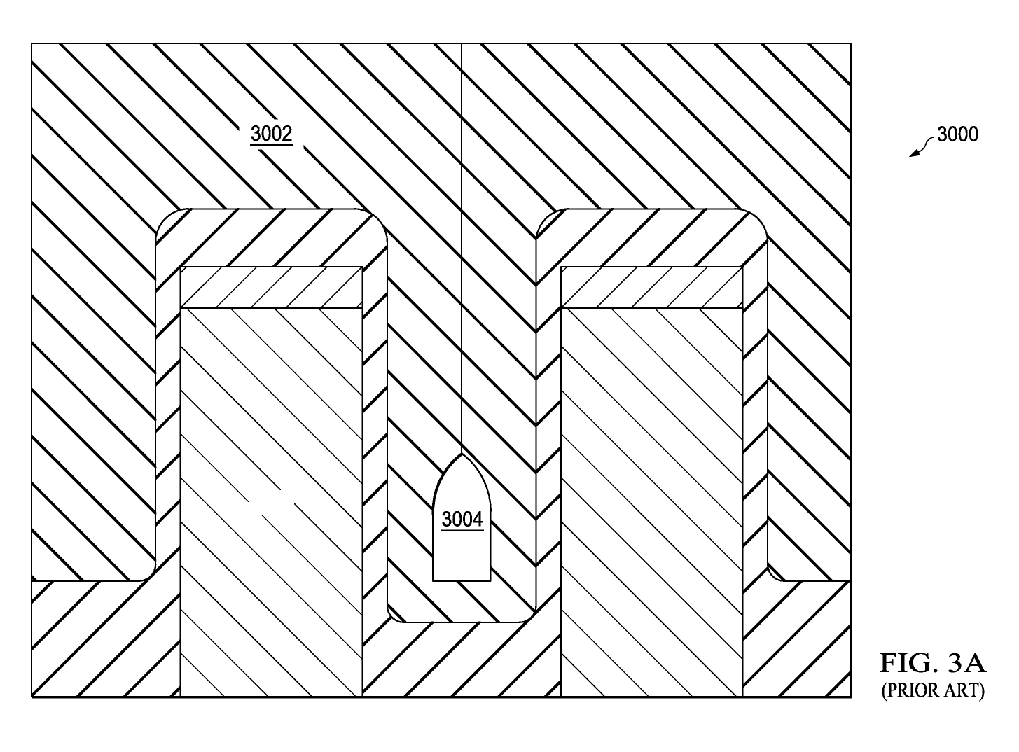

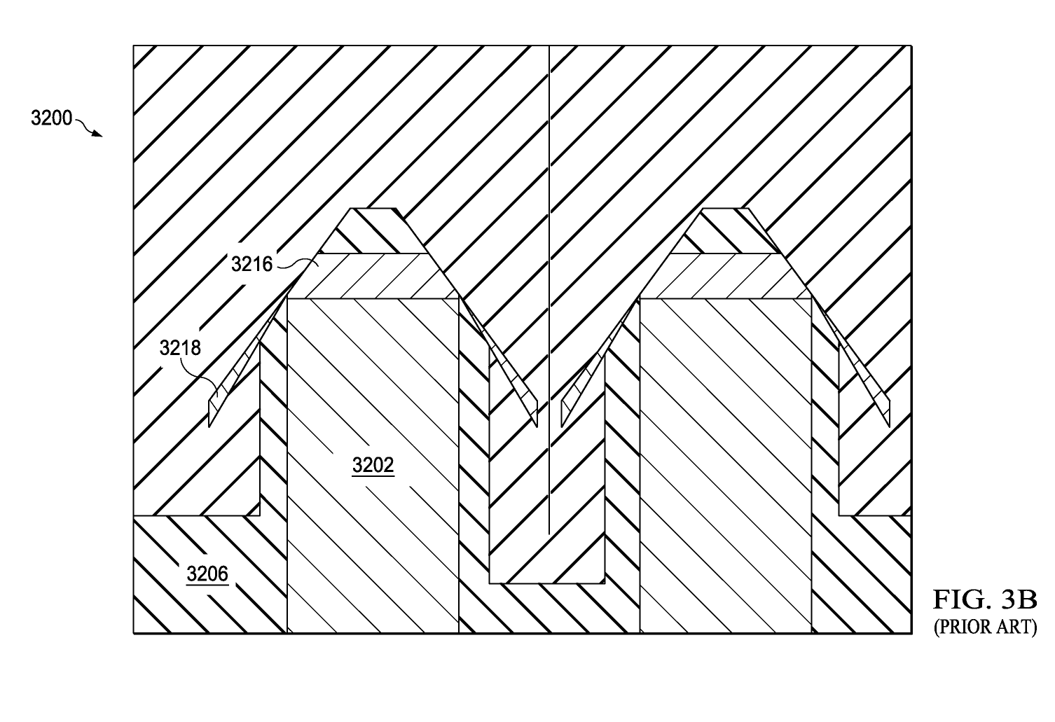

FIG. 3A shows a cross section, (3000) through a void (3004) formed in a high aspect ratio gap (about 3.3) after the second step dielectric deposition (3002) using a conventional HDP gapfill process. The E/D ratio used to deposit the gapfill dielectric is approximately 0.20.

FIGS. 3B shows a cross section, (3200) of filaments (3218) that may be formed and may cause reliability problems when the E/D ratio of a conventional HDP gapfill process is adjusted to eliminate voids. Increasing the E/D ratio in the second deposition step of a conventional process to approximately 0.25 may eliminate voids but may also sputter etch the top corners (3216) of the metal leads (3202) as shown in FIG. 3B. Some of the sputtered material may redeposit to form metallic filaments (3218). These filaments may be partially conductive and may reduce the breakdown voltage between the two metal leads (3202) leading to reliability failures.

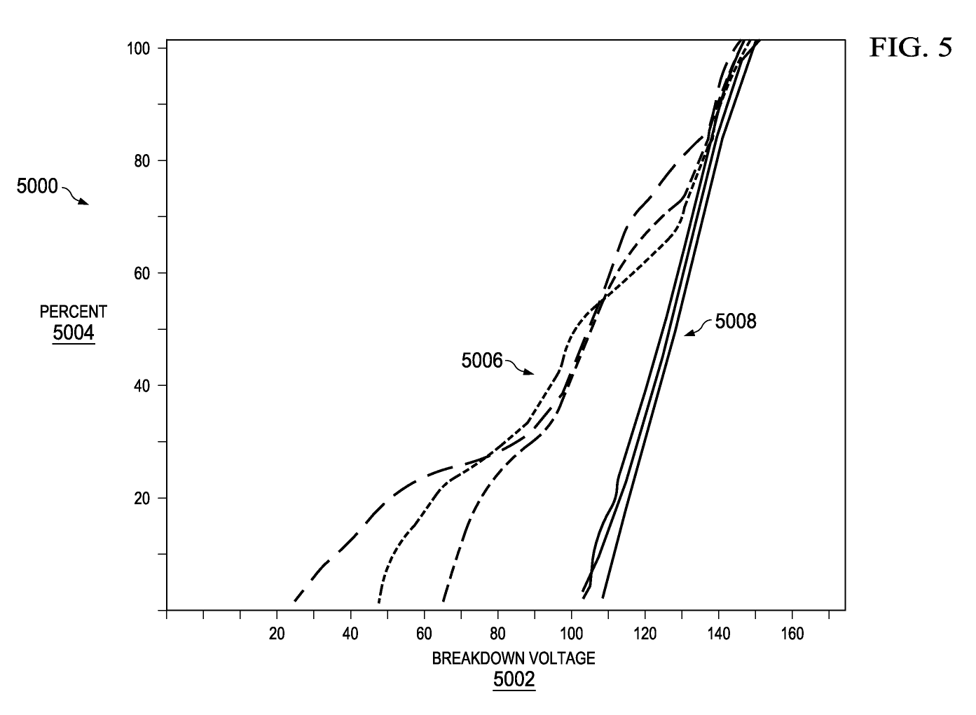

Electrical breakdown curves (5006) between two metal leads with metal filaments (3218) such as those shown in FIG. 3B are given in the graph (5002) in FIG. 5. Each of the three breakdown curves (5006) includes the breakdown voltage from all die across each of three wafers. The breakdown distributions (5006) between metal leads with metal filaments is broad ranging from about 30 volts to about 130 volts. Electrical breakdown curves (5008) from wafers with a HDP gapfill process according to an embodiment of the instant invention have tight breakdown distributions ranging from about 100 to 130 volts as shown in the graph (5002).

In an embodiment of the instant invention it was discovered that reducing the deposition rate of the step one liner deposition by lowering the LFRF and also lowering the reactant (SiH4 and O2) flow rates and also increasing the E/D ratio during the first step liner deposition to be approximately the same or greater than the E/D ratio during the second gap fill deposition by increasing the HFRF power, produces a liner with a continuously sloping profile over the top corners of the gap with no damage to the top corners as shown in FIG. 2. This continuously sloping profile significantly facilitates the filling of high aspect ratio gaps without producing voids.

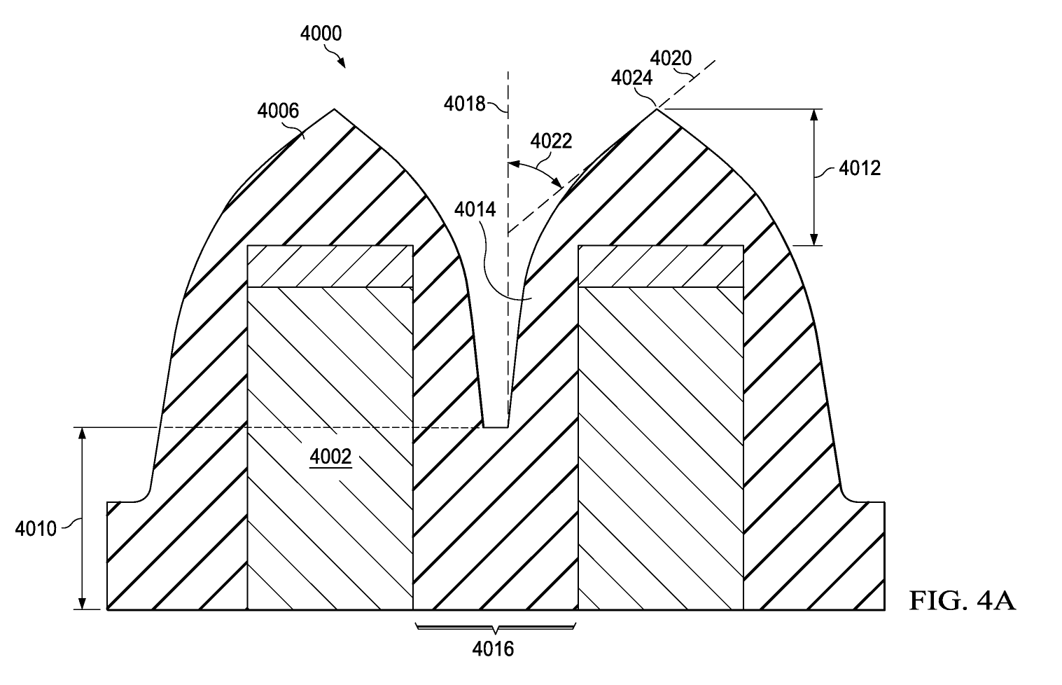

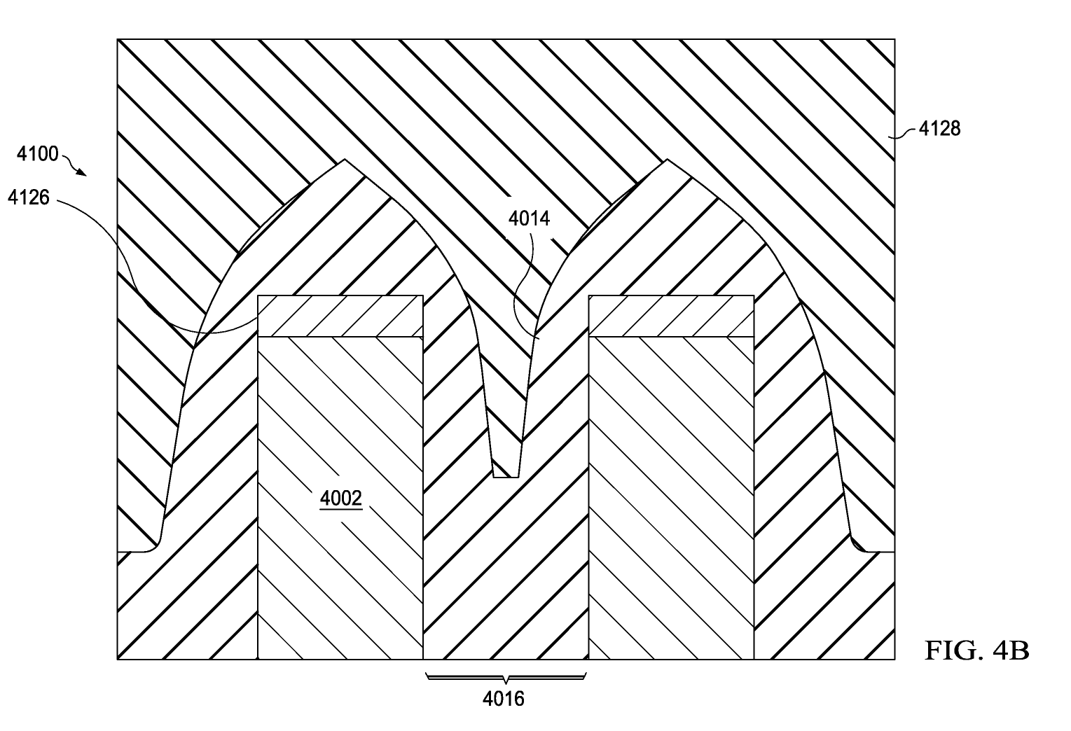

FIG. 4A is a cross section illustrating the dielectric profile after the HDP liner deposition according to an embodiment of the instant invention. The minimum width metal leads (4002) plus TiN caps (4004) are approximately 660 nm tall, 300 nm wide, and are separated by approximately 200 nm for an aspect ratio of about 3.3. The liner which is deposited in the first gapfill step according to an embodiment decreases the aspect ratio of the gap. The thickness on top (4012) of the lead (4002) is less than the thickness in the bottom (4010) of the gap (4016). In addition the profile (4014) on the sides of the gap (4016) is sloped which significantly facilitates void free gapfill during step 2 of the HDP gapfill deposition process. The angle (4022) between a line (4020) that is tangent to the surface of the dielectric liner (4006) and passes through the peak (4024) of the dielectric liner that forms in the top center of a minimum width lead (4002) may be in the range of 30 degrees to 60 degrees and preferable in the range of 42 to 48 degrees. Example process deposition ranges and a set of preferred embodiment conditions for the step 1 HDP liner gapfill deposition are listed in Table 1. The deposition pressure is low in the range of 2 to 3 milliTorr, the deposition temperature is in the range of 380 to 395 C, and the E/D ratio is in the range of 0.2 to 0.24. The flow rates of SiH4 (51 sccm to 61 sccm) and O2 (80 sccm-90 sccm) are kept low to reduce the deposition rate and the high frequency power is kept somewhat high (2400 watts to 3000 watts) to achieve an E/D ratio of about 0.22 and the desired sloped profile (4020) on the sides of the gap (4016).

TABLE 1
HDP Step 1 Liner

| | | Preferred | |
|---|---|---|---|
| ITEM | RANGE | Embodiment | UNITS |
| Hi-Freq. Power | 2400-3000 | 2700 | watts |
| Lo-Freq. Power | 1700-2300 | 2000 | watts |
| Pressure | 2-3 | 2.5 | mtorr |
| Temperature | 380-395 | 383 | C. |
| SiH4 | 51-61 | 56 | sccm |
| O2 | 80-90 | 85 | sccm |
| Ar | 40-50 | 45 | sccm |
| E/D | .20-.24 | 0.22 | |

FIG. 4B is a crossection (4100) of a gap filled according to an embodiment of the instant invention after the second step HDP gapfill dielectric (4128) is deposited. The gap (4016) has been filled without a void and without damage to the top corners (4126) of the metal leads (4002). Example process flow ranges and a set of preferred embodiment conditions for the step 2 HDP gapfill deposition are given in Table 2. Because the sloped sidewalls of the gap (4014) from the liner according to the embodiment liner deposition greatly facilitate void free gapfill during HDP step 2, step 2 deposition recipes other than the preferred embodiment may be used to fill the gap without forming voids. In the preferred recipe given in Table 2, an E/D ratio of 0.19 is used for the gapfill step which unlike conventional HDP gapfill process flows is lower than the E/D ratio (0.22) of the liner step.

TABLE 2
HDP Step 2 Gapfill

| | | Preferred | |
|---|---|---|---|
| ITEM | RANGE | Embodiment | UNITS |
| Hi-Freq. Power | 3300-3800 | 3550 | watts |
| Lo-Freq. Power | 2750-3250 | 3000 | watts |
| Pressure | 2-3 | 2.5 | mtorr |
| Temperature | 380-395 | 383 | C. |
| SiH4 | 75-85 | 80 | sccm |
| O2 | 110-130 | 120 | sccm |
| Ar | 40-50 | 45 | sccm |
| E/D | .15-.23 | 0.19 | |

High aspect ratio metal leads have been used to illustrate this embodiment, but other high aspect ratio gaps that may be formed between other structures such as gates in FLASH transistors or may be formed between active geometries may also be filled without voids with this embodiment.

The embodiment described above is a two step HDP process. It may be appreciated that those skilled in the art may add one or more additional deposition steps to the process and still utilize the ideas of this embodiment.

The embodiment described above is for HDP SiO2 deposition, but films containing nitrogen by incorporating a nitrogen containing gas such as, N2, NO or NH3 for example or incorporating dopant gases such as boron, fluorine, phosphorus, and arsenic containing gases may also be deposited.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method of fabricating an integrated circuit device comprising:
providing a semiconductor substrate;
providing features overlying said semiconductor substrate wherein trenches between said features are termed gaps;
depositing a dielectric liner overlying said features and lining said gaps, wherein said depositing is by high density plasma (HDP) chemical vapor deposition (CVD) and wherein there is a continuously increasing downward slope of the surface of said dielectric liner from a peak of said dielectric liner on a top center of a minimum width one of said features to the surface of said dielectric on side walls of said gap; and
depositing a dielectric gapfill layer overlying said dielectric liner layer and filling said gaps.

2. The method in claim 1 wherein an angle between a line that is tangent to said dielectric liner at said peak and a vertical line is in the range of 30 degrees to 60 degrees.

3. The method in claim 2 wherein said angle is between 42 degrees and 48 degrees.

4. The method of claim 1 wherein a first E/D ratio during said depositing of said dielectric liner is at least as large as a second E/D ratio during said depositing of said dielectric gapfill.

5. The method of claim 4 wherein said said first E/D ratio is 0.22 and said second E/D ratio is 0.19.

6. The method of claim 1 wherein said dielectric liner layer is silicon dioxide and wherein reactant gases are SiH4, O2, and Ar.

7. The method of claim 6 wherein during said depositing said dielectric liner layer a E/D ratio ranges from 0.20 to 0.24 and where a deposition pressure ranges from 2 to 3 milliTorr.

8. The method of claim 7 wherein during said depositing said silicon dioxide a temperature ranges from 380 C to 395 C, a SiH4 flow ranges from 51 to 61 sccm, a O2 flow ranges from 80 to 90 sccm, an Ar flow ranges from 40 to 50 sccm, a HFRF ranges from 2400 to 3000 watts, and a LFRF ranges from 1700 to 2300 watts.

9. The method of claim 8 wherein said E/D ratio is 0.22, said pressure is 2.5 milliTorr, said temperature is 383 C, said SiH4 flow is 56 sccm, said O2 flow is 85 sccm, said Ar flow is 45 sccm, said HFRF is 2700 watts, and said LFRF is 2000 watts.

10. The method of claim 1 wherein said dielectric gapfill layer is silicon dioxide and wherein reactant gases are SiH4, O2, and Ar.

11. The method of claim 10 wherein during said depositing of said dielectric gapfill layer a E/D ratio ranges from 0.15 to 0.23 and where a deposition pressure ranges from 2 to 3 milliTorr.

12. The method of claim 11 wherein during said depositing said silicon dioxide a temperature ranges from 380 C to 395 C, a SiH4 flow ranges from 75 to 85 sccm, a O2 flow ranges from 110 to 130 sccm, an Ar flow ranges from 40 to 50 sccm, a HFRF ranges from 3300 to 3800 watts, and a LFRF ranges from 2750 to 3250 watts.

13. The method of claim 12 wherein said E/D ratio is 0.19, said pressure is 2.5 milliTorr, said temperature is 383 C, said SiH4 flow is 80 sccm, said O2 flow is 120 sccm, said Ar flow is 45 sccm, said HFRF is 3550 watts, and said LFRF is 3000 watts.

14. The method of claim 6 wherein said step of depositing said dielectric liner further comprises adding a nitrogen containing gas to said reactant gases.

15. The method of claim 10 wherein said step of depositing said dielectric gapfill further comprises adding a dopant gas to said reactant gases wherein said dopant gas is a source of one of the group of: fluorine, boron, phosphorus, and arsenic.

16. A method for fabricating an integrated circuit device comprising:
providing a semiconductor substrate;
providing features overlying said semiconductor substrate wherein trenches between said features are termed gaps;
depositing a silicon dioxide liner layer overlying said features, wherein said depositing is by HDP CVD using silane, oxygen, and argon process gases wherein said depositing comprises an E/D ratio ranging from 0.20 to 0.24 and wherein a deposition pressure ranges from 2 to 3 milliTorr; and
depositing a silicon dioxide gapfill layer overlying said silicon dioxide liner layer using HDP CVD using silane, oxygen, and argon process gases and filling said gaps.

17. The method in claim 16 wherein there is a continuously increasing downward slope of the surface of said dielectric liner from a peak of said dielectric liner on a top center of a minimum width feature to the surface of said dielectric on side walls of said gap and wherein an angle between a line that is tangent to said dielectric liner at said peak and a vertical line is in the range of 30 degrees to 60 degrees.

18. The method in claim 17 wherein said angle is between 42 degrees and 48 degrees.

19. The method of claim 16 wherein a first E/D ratio during said depositing said silicon dioxide liner layer is at least as large as a second E/D ratio during said depositing said silicon dioxide gapfill layer.

20. The method of claim 19 wherein said first E/D ratio is 0.22 and said second E/D ratio is 0.19

21. The method of claim 16 wherein during said depositing said silicon dioxide liner layer a temperature ranges from 380 C to 395 C, a SiH4 flow ranges from 51 to 61 sccm, a O2 flow ranges from 80 to 90 sccm, an Ar flow ranges from 40 to 50 sccm, a HFRF ranges from 2400 to 3000 watts, and a LFRF ranges from 1700 to 2300 watts.

22. The method of claim 21 wherein said E/D ratio is 0.22, said pressure is 2.5 milliTorr, said temperature is 383 C, said SiH4 flow is 56 sccm, said O2 flow is 85 sccm, said Ar flow is 45 sccm, said HFRF is 2700 watts, and said LFRF is 2000 watts.

23. The method of claim 16 wherein during said depositing said silicon dioxide gapfill layer a pressure ranges from 2 to 3 milliTorr, a temperature ranges from 380 C to 395 C, a SiH4 flow ranges from 75 to 85 sccm, a O2 flow ranges from 110 to 130 sccm, an Ar flow ranges from 40 to 50 sccm, a HFRF ranges from 3300 to 3800 watts, and a LFRF ranges from 2750 to 3250 watts, and an E/D ratio ranges from 0.15 to 0.23.

24. The method of claim 23 wherein said E/D ratio is 0.19, said pressure is 2.5 milliTorr, said temperature is 383 C, said SiH4 flow is 80 sccm, said O2 flow is 120 sccm, said Ar flow is 45 sccm, said HFRF is 3550 watts, and said LFRF is 3000 watts.

25. The method of claim 16 wherein said step of depositing said silicon dioxide liner further comprises adding a nitrogen containing gas to said process gases.

26. The method of claim 16 wherein said step of depositing said silicon dioxide gapfill further comprises adding a dopant gas to said process gases wherein said dopant gas is a source of one of the group of: fluorine, boron, phosphorus, and arsenic.
